(19) United States
(12) Patent Application Publication
(10) Pub. No.: US 2011/0254048 A1
(43) Pub. Date: Oct. 20, 2011

(54) GROUP III NITRIDE SEMICONDUCTOR EPITAXIAL SUBSTRATE

(75) Inventors: Hiroshi Amano, Aichi (JP); Akira Bando, Saitama (JP)

(73) Assignee: SHOWA DENKO K.K., Tokyo (JP)

(21) Appl. No.: 12/671,660

(22) PCT Filed: Aug. 6, 2008
(86) PCT No.: PCT/JP2008/064501

§ 371 Date: Feb. 1, 2010

(30) Foreign Application Priority Data
Aug. 9, 2007 (JP) 2007-208496

(51) Int. Cl. H01L 29/20; H01L 33/30

(52) U.S. Cl. 257/103; 257/615; 257/E29.089; 257/E33.023

(57) ABSTRACT

An object of the present invention is to provide a Group III nitride semiconductor epitaxial substrate, i.e., an AlₓGa₁₋ₓN (0≦x≦1) epitaxial substrate succeeding in reducing the generation of cracking or dislocation, and enhancing the crystal quality. More specifically, an object of the present invention is to provide an AlₓGa₁₋ₓN (0<x≦1) epitaxial substrate useful for a light-emitting device in the ultraviolet or deep ultraviolet region. The inventive Group III nitride semiconductor epitaxial substrate comprises a base and an AlₓGa₁₋ₓN (0≦x≦1) layer stacked on the base, wherein a layer allowing a crystal having −C polarity and a crystal having +C polarity to coexist is present on the base side of the AlₓGa₁₋ₓN (0≦x≦1) layer.

### TECHNICAL FIELD

The present invention relates to a Group III nitride semiconductor epitaxial substrate. More specifically, the present invention relates to a Group III nitride semiconductor epitaxial substrate suitable for a light-emitting device in the ultraviolet or deep ultraviolet region.

### BACKGROUND ART

Conventionally, a Group III nitride semiconductor has been utilized as a functional material for fabricating a Group III nitride semiconductor light-emitting device having a pn junction-type structure capable of emitting visible light at a short wavelength, such as a light-emitting diode (LED) and laser diode (LD). In this case, in order to enhance the quality of the light-emitting layer, for example, at the time of fabricating an LED using gallium indium nitride (GaInN) for the light-emitting layer and emitting light in the blue or green band, gallium nitride (GaN) is formed on a substrate to a thickness of several μm (hereinafter referred to as an “underlying layer”) so as to not only improve crystallinity but also facilitate light extraction. Also, in the production of a device requiring higher-quality crystallinity, such as a LD, in order to further enhance the crystallinity of the underlying layer, dislocation is reduced by processing the substrate or underlying layer and depositing a crystal thereon. In addition, a free-standing GaN substrate is used so as to further reduce the dislocation density.

On the other hand, in a light-emitting device using gallium nitride, aluminum gallium nitride or aluminum nitride for the light-emitting layer and emitting light in the ultraviolet or deep ultraviolet region, since GaN absorbs light at a wavelength of 360 nm or less, the light released from the light-emitting layer is absorbed and light emission efficiency is decreased. Also, cracking tends to occur in the Al_{y}Ga_{1-y}N (0<y≦1) layer on GaN layer due to the difference in the lattice constant and in the thermal expansion coefficient, and therefore hinders the production of a device. Cracking is more conspicuous as the Al composition becomes larger, and its effect is greater in a short-wavelength device having a larger Al composition.

In order to solve this problem, a light-emitting layer needs to be produced at least on a substance that does not absorb light released from the light-emitting layer. For example, in the case of forming an Al_{y}Ga_{1-y}N (0<y≦1) layer as an active layer, the AlₓGa₁₋ₓN (0<x≦1) used as the underlying layer must satisfy y<x. Accordingly, it is preferred that AlGaN used as the underlying layer has as high an AlN mol fraction as possible. However, conventionally, as the AlN mol fraction of AlGaN is higher, a good-quality crystal is more difficult to obtain. This is because AlN has a higher melting point and very low vapor pressure and also in view of crystal growth, the Al atom during AlN growth does not readily undergo surface migration compared with a Ga atom during GaN crystal growth, making it difficult to match the crystal lattice.

As for the method for solving this problem, in recent crystal growth technology using a MOVPE or MBE method, a high-quality AlN layer is obtained by accelerating migration of the Al atom by alternately supplying a Al raw material and a N raw material when growing AlN on an SiC or sapphire substrate (see, APPLIED PHYSICS LETTERS, Vol. 81, 4392-4394 (2002)). However, this method has a problem in that the crystal growth rate is low and productivity is bad.

Furthermore, a technique of stacking heterogeneous ultrathin film layers for several cycles or hundreds of cycles has been proposed as the method for improving crystal quality (see, Journal of Crystal Growth, Vol. 298, 345-348 (2007)), but stacking for hundreds of cycles results in bad productivity. Such a method is unsuitable for the production of a light-emitting device, because a fairly large film thickness is necessary to produce a light-emitting device such as an LED and LD.

For these reasons, stacking of an AlₓGa₁₋ₓN (0<x≦1) layer to a thickness of several μm or more on a sapphire or SiC substrate by relatively increasing the growth rate is a very important technique for producing a light-emitting device in the ultraviolet or deep ultraviolet region. In order to meet this requirement, for example, a template substrate obtained by stacking AlN on a sapphire base has been developed (see, Japanese Patent No. 3,768,943). As for this template substrate, in view of crystallinity of the AlN layer itself, uniformity in the plane orientation of the C-plane crystal face is very good, but uniformity of the crystal orientation in the rotation direction of C-axis is not good. Furthermore, use of this template substrate produces a low-dislocation effect on GaN or AlGaN having a relatively low AlN mol fraction stacked thereon, but as the AlN mol fraction increases, the low-dislocation effect decreases, making it difficult to obtain a good-quality AlGaN crystal (see, Physica Status Solidi C, Vol. 0, 2444-2447 (2003)).

In summary, when GaN is stacked on a conventional AlN template substrate or a free-standing GaN substrate is used, the light released from the light-emitting layer is absorbed by GaN. Also, when AlGaN having a high Al composition is deposited on GaN, deterioration of the device such as cracking, is caused in the AlGaN layer due to the difference in the lattice constant and in the thermal expansion coefficient.

In order to solve these problems, an AlGaN substrate having a composition allowing transmission of light at the emission/receiving wavelength must be used to realize no light absorption and high light emission/receiving efficiency. Furthermore, difference in the lattice constant and in the thermal expansion coefficient between the AlGaN substrate and the light emitting/receiving layer needs to be reduced so as to suppress generation of cracking or dislocation in the light emitting/receiving layer and thereby enhance the crystal quality. In addition, generation of cracking or dislocation in the AlGaN substrate itself needs to be suppressed so as to enhance the crystal quality. However, the crystal quality of AlₓGa₁₋ₓN (0<x≦1) as the AlGaN substrate is not satisfied. In particular, AlₓGa₁₋ₓN (0<x≦1) having a high AlN mol fraction is characteristically close to AlN having a high melting point and a low vapor pressure compared with GaN, and therefore is difficult to undergo good crystal growth.

### DISCLOSURE OF THE INVENTION

In view of these problems, an object of the present invention is to provide a Group III nitride semiconductor epitaxial substrate, i.e., an AlₓGa₁₋ₓN (0≦x≦1) epitaxial substrate succeeding in reducing the generation of cracking or dislocation and enhancing the crystal quality. More specifically, an object of the present invention is to provide an AlₓGa₁₋ₓN (0<x≦1) epitaxial substrate useful for a light-emitting device in the ultraviolet or deep ultraviolet region.

In the present invention, at the time of growing a Group III nitride semiconductor crystal such as GaN or AlₓGa₁₋ₓN (0<x≦1) in the <0001> axis direction on a base (C-plane growth), a crystal having +C polarity (Group III polar plane crystal) and a crystal having −C polarity (nitrogen polar plane crystal) are allowed to coexist in the crystal so as to obtain a high-quality AlₓGa₁₋ₓN (0≦x≦1).

That is, the present invention provides the following inventions.

(1) A Group III nitride semiconductor epitaxial substrate comprising a base and an AlₓGa₁₋ₓN (0≦x≦1) layer stacked on the base, wherein a layer allowing a crystal having −C polarity and a crystal having +C polarity to coexist is present on the base side of the AlₓGa₁₋ₓN (0≦x≦1) layer.

(2) The Group III nitride semiconductor epitaxial substrate according to (1) above, wherein the surface layer opposite the base side of the AlₓGa₁₋ₓN (0≦x≦1) layer is composed of only a crystal having +C polarity.

(3) The Group III nitride semiconductor epitaxial substrate according to (1) or (2) above, wherein the range of x in the AlₓGa₁₋ₓN (0≦x≦1) layer is (0<x≦1).

(4) The Group III nitride semiconductor epitaxial substrate according to any one of (1) to (3) above, wherein in the layer allowing a crystal having −C polarity and a crystal having +C polarity to coexist, both the −C polarity crystal and the +C polarity crystal have a grain diameter of 10 to 5,000 nm.

(5) The Group III nitride semiconductor epitaxial substrate according to any one of (1) to (4) above, wherein the X-ray full width at half maximum of the (10-10) asymmetric plane of the AlₓGa₁₋ₓN (0≦x≦1) layer is 400 seconds or less.

(6) The Group III nitride semiconductor epitaxial substrate according to any one of (1) to (5) above, wherein the AlₓGa₁₋ₓN (0≦x≦1) layer is deposited using an MOVPE method.

(7) The Group III nitride semiconductor epitaxial substrate according to (6) above, wherein the layer allowing a crystal having −C polarity and a crystal having +C polarity to coexist is deposited in the range of a V/III ratio of 20 to 2,000.

(8) The Group III nitride semiconductor epitaxial substrate according to (6) or (7) above, wherein the V/III ratio when depositing the layer composed of only a crystal having +C polarity is smaller than the V/III ratio when depositing the layer allowing a crystal having −C polarity and a layer having +C polarity to coexist.

(9) The Group III nitride semiconductor epitaxial substrate according to any one of (6) to (8) above, wherein the layer allowing a crystal having −C polarity and a crystal having +C polarity to coexist is deposited at a temperature of 1,250° C. or more.

(10) The Group III nitride semiconductor epitaxial substrate according to any one of (1) to (9) above, wherein at least one member selected from sapphire, SiC, Si, ZnO and Ga₂O₃ is used for the base.

(11) A Group III nitride semiconductor device obtained using the Group III nitride semiconductor epitaxial substrate according to any one of (1) to (10) above.

(12) A Group III nitride semiconductor ultraviolet or deep ultraviolet light-emitting device obtained using the Group III nitride semiconductor epitaxial substrate according to (2) above.

The Group III nitride semiconductor epitaxial substrate of the present invention ensures suppressed generation of cracking or dislocation and enhanced crystal quality and in turn, the Group III nitride semiconductor stacked thereon is also reduced in the generation of cracking or dislocation and enjoys enhanced crystal quality. Accordingly, the present invention is effective as the substrate of a Group III nitride semiconductor device.

In particular, the AlₓGa₁₋ₓN (0<x≦1) epitaxial substrate of the present invention is effective in producing a light emitting/receiving device in the ultraviolet or deep ultraviolet region of 360 nm or less, of which application in the field of medicine or precision processing is expected.

### BRIEF DESCRIPTION OF THE DRAWINGS

FIG. 1 is a view schematically illustrating the cross-sectional structure of the Group III nitride semiconductor epitaxial substrate of the present invention produced in Example 1.

FIG. 2 is a view schematically illustrating the cross-section of the semiconductor stacked structure produced in Example 2.

FIG. 3 is a schematic view illustrating the cross-section of the light-emitting device fabricated in Example 2.

FIG. 4 is a view schematically illustrating the cross-sectional structure of the AlN epitaxial substrate produced in Comparative Example 1.

### BEST MODE FOR CARRYING OUT THE INVENTION

In the present invention, at the time of growing a Group III nitride semiconductor crystal, such as GaN or AlₓGa₁₋ₓN (0<x≦1) in the <0001> axis direction on a base (C-plane growth), a crystal having +C polarity (Group III polar plane crystal) and a crystal having −C polarity (nitrogen polar plane crystal) are allowed to coexist so as to obtain a high-quality AlₓGa₁₋ₓN (0≦x≦1) crystal.

That is, when a crystal having +C polarity and a crystal having −C polarity are allowed to coexist, a dislocation is bent along the crystal grain boundary and a low-dislocation effect is realized. An AlₓGa₁₋ₓN (0≦x≦1) layer where −C polarity and +C polarity are mixed is formed on a base. Thereafter, the +C polarity crystal gradually covers the −C polarity crystal by utilizing the property that the +C polarity crystal is more liable to grow in the transverse direction than the −C polarity crystal. At this time, a dislocation is bent at the boundary between the +C polarity crystal and the −C polarity crystal. Finally, the +C polarity crystal covers the entire −C polarity crystal, and only the +C polarity crystal is formed in the crystal top.

In order to judge the polarity, CBED (convergent-beam electron diffraction) using electron beam diffraction is known. However, this method has a problem that the sample needs to be prepared as a thin film of about 100 nm by using a technique such as FIB (focused ion beam) and is difficult to produce and also, the measurement region is narrow. Furthermore, in the case of a ternary mixed crystal, such as AlₓGa₁₋ₓN (0<x≦1), there is a problem in the precision due to the effect of local non-uniformity of the composition. On the other hand, judgment by etching is simple and easy and enables observing a wide region at the same time. This judgment utilizes a difference in the etching rate between the −C polarity crystal and the +C polarity crystal, so that once etching conditions are established, the polarity can be relatively easily judged. In the present invention, a method of dipping an epitaxial wafer in a 8 mol KOH solution at room temperature for 10 minutes is employed. At this time, a part of the epitaxial layer is masked with a substance resistant to KOH, such as gold. After the etching, the wafer is washed with water and dried, the mask is removed using a chemical that does not react with the AlₓGa₁₋ₓN (0≦x≦1) layer and dissolves only the mask (for example, when gold is used for the mask, aqua regia), and the difference in level between the portion protected with the mask and the portion unprotected and etched with an aqueous KOH solution is measured by a stylus profilometer, a laser microscope or the like. From the dipping time and the difference in level, the etching rate of the AlₓGa₁₋ₓN (0≦x≦1) layer for an aqueous KOH solution is determined. The polarity is judged as +C polarity when the etching rate is less than 0.1 μm/hr, and judged as −C polarity when 0.1 μm/hr or more.

In the present invention, the base used for stacking a Group III nitride semiconductor thereon may be, for example, a base composed of an oxide single crystal material such as sapphire (α-Al₂O₃ single crystal), zinc oxide (ZnO) or gallium oxide (compositional formula: Ga₂O₃), or a Group IV semiconductor single crystal such as silicon single crystal (silicon) or cubic or hexagonal crystalline silicon carbide (SiC), which are materials having a relatively high melting point and heat resistance. However, the plane orientation on the base crystal surface needs to be selected such that the C plane of a hexagonal crystal of Group III nitride semiconductor composed of GaN or AlₓGa₁₋ₓN (0<x≦1) grows.

The Group III nitride semiconductor epitaxial substrate of the present invention comprises a base and a Group III nitride semiconductor of GaN or AlₓGa₁₋ₓN (0<x≦1) formed on the base. The Group III nitride semiconductor having the above-described composition can be formed by vapor phase growing means such as metal-organic chemical vapor deposition (simply referred to as MOVPE, MOCVD, OMVPE or the like), molecular beam epitaxy (MBE) and hydride vapor phase epitaxy (HVPE). Regarding the AlN crystal, a sublimation method or a liquid phase growth method can also be used. Among these methods, MOVPE is preferred.

This is because the vapor phase growth method facilitates production of an AlGaN mixed crystal compared with the liquid phase method and above all, the MOVPE method enables easier control of the composition than the HVPE method and obtaining a higher growth rate than the MBE method.

The MOVPE method uses, for example, hydrogen (H₂) or nitrogen (N₂) as the carrier gas, trimethyl gallium (TMG) or triethyl gallium (TEG) as the Ga source that is a Group III raw material, trimethyl aluminum (TMA) or triethyl aluminum (TEA) as the Al source that is a Group III raw material, trimethyl indium (TMI) or triethyl indium (TEI) as the In source that is a Group III raw material, and ammonium (NH₃) or hydrazine (N₂H₄) as the nitrogen source.

In order to allow a +C polarity crystal and a −C polarity crystal to coexist in the Group III nitride semiconductor, various growth conditions must be controlled according to the composition of the Group III nitride semiconductor. Production conditions and the like of the Group III nitride semiconductor epitaxial substrate of the present invention are described below by taking AlₓGa₁₋ₓN (0<x≦1) as an example.

In order for a +C polarity crystal and a −C polarity crystal to coexist in the Group III nitride semiconductor, in view of physical properties of AlN, it is preferred to grow AlₓGa₁₋ₓN (0<x≦1) at a high temperature. In particular, when the MOVPE method is used, the growth temperature and the ratio of Group V element/Group III element in the raw materials supplied (hereinafter referred to as a “V/III” ratio) must be adjusted. By adjusting the growth temperature and the V/III ratio, a +C polarity crystal and a −C polarity crystal can be mixed and furthermore, the conditions facilitating growth of a +C polarity crystal and the conditions facilitating growth of a −C polarity crystal can also be controlled.

As described in Japanese Patent No. 3,768,943 supra, nitridation of the base is conventionally necessary for forming a −C polarity plane (particularly in the case of sapphire). However, the −C polarity plane is very weak in the chemical property compared with +C polarity plane and is not readily applicable to a light emitting/receiving device, and use of a +C polarity plane is usually required. The present invention enables formation of a crystal having a −C polarity plane and a crystal having +C polarity plane at the same time without a nitridation treatment of the base, and this method produces a great effect of reducing dislocation.

The MOVPE method is excellent as a crystal growth method because of its capability of producing AlGaN with excellent composition controllability and high productivity.

By utilizing this method for a light emitting/receiving device such as LED, LD or light-receiving device in the ultraviolet or deep ultraviolet region at a wavelength of about 360 nm to 200 nm, a device having a higher light emission/receiving efficiency than conventional devices can be fabricated. Also, significant enhancement of crystallinity can be expected and therefore, a conventionally unrealizable light emitting/receiving device in the short-wavelength region can be realized.

In the MOVPE method, a Group III nitride semiconductor according to the purpose is preferably grown on a base by using the above-described raw materials in a temperature range of 1,250° C. or more, because if the temperature is 1,250° C. or less, the crystal quality deteriorates in AlₓGa₁₋ₓN (0<x≦1) having a high Al composition.

In the early stage of growth, the AlₓGa₁₋ₓN (0<x≦1) layer is grown in a relatively high V/III ratio at a high temperature of 1,250° C. or more. Thanks to such conditions, in the early stage of growth, the Group III raw material readily reacts with the nitrogen source or a nitrogen atom resulting from decomposition of the nitrogen source, and an AlₓGa₁₋ₓN (0<x≦1) layer having −C polarity that is scarcely producible by a normal V/III ratio is produced on the base surface. As a result, mixing of an AlₓGa₁₋ₓN (0<x≦1) layer region having −C polarity and an AlₓGa₁₋ₓN (0<x≦1) layer region having +C polarity occurs on the base surface.

However, with the progress of growth, the +C polarity layer which is liable to grow in the transverse direction, continues growing on the −C polarity layer to cover the −C polarity layer, and at last, a uniform layer composed of only a +C polarity layer is formed. At this time, the dislocation is bent along the grain boundary in the course of the +C polarity layer covering the −C polarity layer, and propagation of the dislocation to the crystal upper layer is inhibited, as a result, a high-quality AlₓGa₁₋ₓN (0<x≦1) layer is obtained.

The V/III ratio may be constant, but when the V/III ratio is set relatively large in the early stage of growth to facilitate growth of the mixed layer and thereafter, the V/III ratio is reduced to preferentially grow the +C polarity layer, a flatter low-dislocation +C polarity layer can be stacked. If the V/III ratio is too large, only a −C polarity layer is formed but a +C polarity layer is not formed and a substrate having a non-flat surface hindering the device production results and cannot be used.

In this way, the ratio of the +C polarity plane to the −C polarity plane can be controlled by changing the V/III ratio, the growth temperature and the like. Also, the growth pressure is expected to have the same effect.

The V/III ratio at the time of growing an AlₓGa₁₋ₓN (0<x≦1) layer where −C polarity and +C polarity are mixed is suitably from 1 to 10,000, preferably from 10 to 5,000, more preferably from 20 to 2,000. Also, in order to obtain a uniform +C polarity layer near the surface on the top of the epitaxial layer, the V/III ratio in this case is suitably from 1 to 2,000, preferably from 5 to 1,000, more preferably from 10 to 500.

As for the growth temperature, a marked effect is obtained at a high temperature of 1,250° C. or more. Since AlN has a high melting point and a low vapor pressure, the optimal growth temperature is estimated to be higher by hundreds of ° C. than GaN. Also, from the standpoint that the decomposition and reaction of ammonia are more accelerated and surface migration of Al is also accelerated, the growth temperature is suitably 1,250° C. or more, preferably 1,300° C. or more, more preferably 1,400° C. or more.

If the temperature is excessively high, crystallinity deterioration or the like of the base occurs. Therefore, the temperature is preferably 1,800° C. or less, more preferably 1,600° C. or less.

The growth rate is preferably high to a certain extent, which is also to facilitate formation of the mixed layer, satisfy the need for growing the +C polarity layer in the transverse direction and furthermore, enhance the productivity. The growth rate is suitably 0.1 μm/hr or more, preferably 0.5 μm/hr or more, more preferably 1 μm/hr or more.

If the growth rate is excessively high, crystallinity deterioration occurs. Accordingly, the growth rate is preferably 20 μm/hr or less, more preferably 10 μm/hr or less.

As for the grain diameter of −C polarity crystal and the grain diameter of +C polarity crystal in the AlₓGa₁₋ₓN (0<x≦1) layer where −C polarity and +C polarity are mixed, if each grain diameter is too small in the early stage of growth on the base, the effect of bending a dislocation present in the grain boundary and in turn, the low-dislocation effect are small, whereas if the grain diameter is excessively large, the +C polarity crystal cannot completely cover the −C polarity crystal and a −C polarity crystal is present even in the upper part crystal, which deteriorates the crystal quality. The grain diameter of −C polarity crystal and the grain diameter of +C polarity crystal are preferably almost equal in the early stage of growth and are suitably from 10 to 5,000 nm, preferably from 50 to 3,000 nm, more preferably from 100 to 2,000 nm.

The crystal grain diameter can be measured by the same method as used for the judgment of polarity. That is, the crystal grain diameter can be measured by a method where an epitaxial wafer is dipped in a 8 mol KOH solution at room temperature for 10 minutes, washed with water and then dried, the surface and cross-section are observed by an optical microscope or an electron microscope, the diameter is measured at several points, for example, 5 points, in each of the +C polarity crystal portion and the −C polarity crystal portion which are present like a mosaic, and the average thereof is taken as the grain diameter.

The ratio between the −C polarity crystal and the +C polarity crystal in the layer in which −C polarity and +C polarity are mixed, is preferably from 2:8 to 8:2, more preferably from 4:6 to 6:4. If the ratio of −C polarity crystal is too large, the −C polarity crystal cannot be completely covered by the +C polarity crystal and disadvantageously remains in the crystal surface, whereas if the ratio of +C polarity crystal is too large, the effect of bending a dislocation generated at the interface with the base becomes small, which is not preferred. It is particularly preferred that the −C polarity crystal and +C polarity crystal are equally present.

The thickness of the layer where −C polarity and +C polarity are mixed is preferably from 0.1 to 5 μm, more preferably from 0.3 to 2 μm. If the thickness is 0.1 μm or less, a dislocation can be hardly bent along the grain boundary and the low-dislocation effect is disadvantageously reduced. An excessively large thickness results in crystallinity deterioration and is also not preferred.

An AlₓGa₁₋ₓN (0<x≦1) layer is grown under the condition of a large V/III ratio to have a thickness in the above-described range and after reducing the V/III ratio, is continuously grown. By virtue of reducing the V/III ratio, a layer where only a +C polarity crystal is present is produced. The total thickness of the AlₓGa₁₋ₓN (0<x≦1) layer is preferably from 1 to 20 μm, more preferably from 3 to 10 μm. If the total thickness is small, flatness after the +C polarity crystal covers the −C polarity crystal is disadvantageously insufficient, whereas if it is excessively large, warpage of the wafer arises, which is not preferred.

The low-dislocation effect by this technique is larger as the Al composition is larger. Accordingly, the Al composition range, i.e., the range of x, of the AlₓGa₁₋ₓN (0<x≦1) layer is preferably 0.2≦x≦1. If x is too small, a −C polarity crystal scarcely grows and the ratio of a −C polarity crystal to a +C polarity crystal disadvantageously becomes small. The range is more preferably 0.5≦x≦1.

As described above, the AlₓGa₁₋ₓN (0≦x≦1) layer of the Group III nitride semiconductor epitaxial substrate of the present invention has a small dislocation density and excellent crystallinity. This is confirmed by the full width at half maximum of the X-ray diffraction peak. The full width at half maximum of the X-ray diffraction peak of the AlₓGa₁₋ₓN (0≦x≦1) layer in the Group III nitride epitaxial substrate of the present invention stands at a value of 200 seconds or less for (0002) plane and a value of 400 seconds or less for (10-10) plane.

A semiconductor stacked structure with functionality is stacked on the Group III nitride semiconductor epitaxial substrate of the present invention, whereby various semiconductor devices can be fabricated.

For example, in the case of forming a stacked structure for a light-emitting device, the structure contains an n-type electrically conducting layer doped with an n-type dopant such as Si, Ge and Sn, a p-type electrically conducting layer doped with a p-type dopant such as magnesium, and the like. Regarding the material, InGaN is widely used for the light-emitting layer and the like, and AlGaN is used for the clad layer and the like. In particular, the present invention is useful as a substrate of an ultraviolet or deep ultraviolet light-emitting device using AlGaN for the light-emitting layer.

As for the device, the substrate may be used for a photoelectric conversion element such as laser device and light-receiving device, an electronic device such as HBT and HEMT, and the like. A large number of semiconductor devices having various structures are known, and the device structure stacked on the Group III nitride semiconductor epitaxial substrate of the present invention, including these device structures, is not limited.

Particularly, in the case of an ultraviolet or deep ultraviolet light-emitting device, a large emission output is obtained when the Group III nitride semiconductor epitaxial substrate of the present invention is used. Therefore, the substrate is useful for applications in the field of medicine, sterilization, microprocessing, illumination and the like, where an ultraviolet or deep ultraviolet light source is effective.

### EXAMPLES

The present invention is described in greater detail below by referring to Examples, but the present invention is not limited to only these Examples.

### Example 1

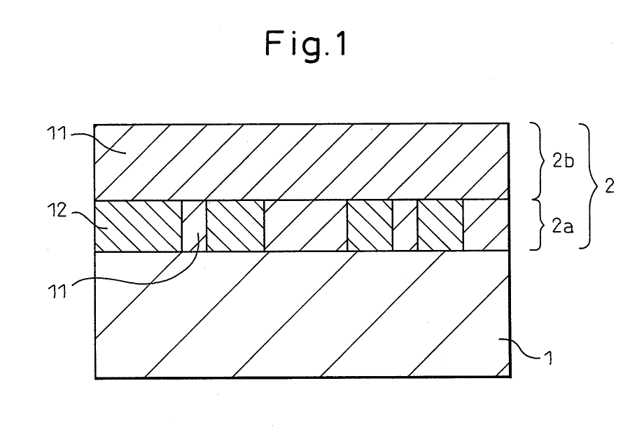

FIG. 1 schematically illustrates the cross-sectional structure of the Group III nitride semiconductor epitaxial substrate of the present invention produced in this Example, where AlN is stacked on a sapphire base. In the Figure, 1 is a substrate, 2 is an AlₓGa₁₋ₓN (0≦x≦1) layer and composed of a layer 2a where a −C polarity crystal and a +C polarity crystal are mixed and a layer 2b where only a +C polarity crystal is present, 11 is a +C polarity crystal, and 12 is a −C polarity crystal.

The structure comprising a sapphire base having stacked thereon AlN is formed using general reduced-pressure MOVPE means by the following procedure. First, a 2 inch-diameter (0001)-sapphire base 1 was placed on a molybdenum susceptor, the susceptor was set in a water-cooled reaction furnace using stainless steel through a load-lock chamber, and a nitrogen gas was supplied to the furnace for purging the inside thereof.

After changing the supplied gas to the vapor phase growth reaction furnace into hydrogen, the inside of the furnace was maintained at 30 Torr. A resistance heating heater was actuated, and the temperature of the base 1 was raised from room temperature to 1,400° C. over 15 minutes. A hydrogen gas was supplied for 5 minutes while maintaining the temperature of the base 1 at 1,400° C., and thermal cleaning of the base 1 surface was thereby carried out.

Thereafter, the temperature of the base 1 was lowered to 1,300° C. and after confirming that the temperature was stabilized at 1,300° C., a hydrogen gas with trimethylaluminum (TMA) vapor was supplied into the vapor phase growth reaction furnace for 10 seconds. As a result, the sapphire base was covered with aluminum atom, or aluminum nitride (AlN) was partially formed through a reaction with nitrogen atom produced due to decomposition of a nitrogen-containing accumulated precipitate that had already adhered to the inner wall of the vapor phase growth reaction furnace. In any case, nitridation of the sapphire base 1 was suppressed.

Subsequently, an ammonia (NH₃) gas was supplied into the vapor phase growth reaction furnace to give a V/III ratio of 500, and an AlN film 2a was grown for 10 minutes.

Furthermore, an ammonia (NH₃) gas and trimethylaluminum (TMA) were adjusted to give a V/III ratio of 100, and the AlN film 2b was further grown for 90 minutes. During the growth, the temperature was monitored by an in-situ monitor for susceptor temperature and reflectance of the epitaxial layer. Also, from the reflectance, the thickness of AlN layer was confirmed to be 4 μm in total.

Supply of trimethylaluminum (TMA) was stopped and after lowering the temperature to 300° C., supply of ammonia was also stopped. Then, the temperature was further lowered to room temperature. The inside of the vapor phase growth reaction furnace was replaced by nitrogen, and the wafer placed on the susceptor was taken out again through a load-lock chamber.

The wafer taken out was free of cracks on the 2 inch-diameter entire surface. The (0002) plane and (10-10) plane were measured for the full width at half maximum of the diffraction peak by an X-ray diffraction apparatus and found to stand at 75 seconds and 350 seconds, respectively, revealing that an AlN layer having very good crystallinity was stacked. For judging the polarity, first, gold was partially vapor-deposited on the epitaxial film of the epitaxial wafer. Next, an aqueous 8 mol/l KOH solution was prepared, and the entire epitaxial wafer was dipped therein at room temperature for 10 minutes. After washing with water, gold was removed using aqua regia. The wafer was again washed with water and dried for 10 minutes. The etching surface was almost uniformly etched and flat. The difference in level was measured at several points by a stylus profilometer and found to be 10 nm on average, from which the etching rate was determined to be 0.06 μm/hr. Since the value is 0.1 μm/hr or less, this was judged as +C polarity, and it was confirmed that the uppermost part of the epitaxial layer entirely has +C polarity.

Incidentally, in order to evaluate an AlN film grown by supplying an ammonia (NH₃) gas for 10 minutes into the vapor phase growth reaction furnace to give a V/III ratio of 500 in the early stage of growth, an epitaxial film formed by not performing but stopping the subsequent growth was judged for polarity in the same manner. The film thickness was 0.5 μm. A clearly etched portion and a scarcely etched portion were present like a mosaic in the portion not protected by a mask, and the area ratio therebetween was nearly 1:1. Also, the etched portion was completely dissolved by etching for 10 minutes, and the etching rate was 3 μm/hr or more. On the other hand, the etching rate of the portion that seemed to be scarcely etched was 0.06 μm/hr. These results reveal that a +C polarity plane and a −C polarity plane are mixed during growth under the growth conditions in the early stage of growth and the ratio therebetween is about 1:1.

Also, the crystal grain diameter was measured according to the following procedure. The epitaxial wafer was dipped in a 8 mol KOH solution at room temperature for 10 minutes, washed with water for 5 minutes and then dried in a clean oven for 5 minutes. Thereafter, the visual field of 10 μm×10 μm of the surface was observed by an electron microscope. Since a portion which is etched and engraved and a portion which is barely etched were present like a mosaic, the diameter was measured at 5 points in each of these regions, and the values obtained were averaged. As a result, the +C polarity crystal grain diameter was 1.0 μm on average, and the −C polarity crystal grain diameter was 0.8 μm on average.

### Example 2

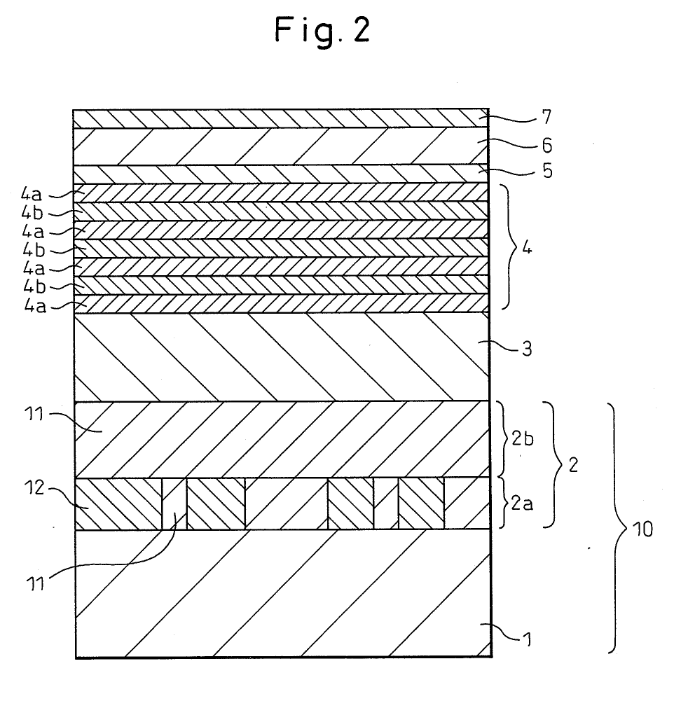

A semiconductor stacked structure having a cross-sectional structure shown in FIG. 2 was produced on the Group III nitride semiconductor epitaxial substrate of the present invention produced in Example 1. In the Figure, as for the numerals 1 and 2, similarly to FIG. 1, 1 is a base, and 2 is an AlₓGa₁₋ₓN (0≦x≦1) layer and is composed of a layer 2a where a −C polarity crystal and a +C polarity crystal are mixed and a layer 2b where only a +C polarity crystal is present. Furthermore, 11 is a +C polarity crystal, 12 is a −C polarity crystal, 3 is an Al_{0.25}Ga_{0.75}N(Si) n-clad layer, 4 is an MQW active layer and composed of an Al_{0.12}Ga_{0.88}N barrier layer 4a and an Al_{0.04}Ga_{0.96}N well layer 4b, 5 is an Al_{0.35}Ga_{0.65}N(Mg) p-electron block layer, 6 is an Al_{0.25}Ga_{0.75}N(Mg) p-clad layer, 7 is a GaN(Mg) p-contact layer, and 10 is the AlN template substrate of the present invention.

As for the production method, the AlN epitaxial substrate produced in Example 1 was again set in the reaction furnace by the same operation as in Example 1, the temperature was raised to 1,100° C. while supplying hydrogen and ammonia (NH₃) gases, and an n-clad layer 3 composed of Al_{0.25}Ga_{0.75}N was stacked to a thickness of 2 μm by adjusting the supplied amounts of raw materials trimethylaluminum (TMA) and trimethylgallium (TMG) such that the AlN mol fraction of AlGaN becomes 25%. At this time, n-type doping was applied using tetramethylsilane (TMSi) as the raw material. Subsequently, an MQW active layer 4 including four barrier layers 4a each composed of AlGaN having an AlN mol fraction of 12% (layer thickness: 8 nm) and three well layers 4b each composed of AlGaN having an AlN mol fraction of 4% (layer thickness: 3 nm) was stacked. After lowering the growth temperature to 1,050° C., a p-electron block layer 5 composed of AlGaN having an AlN mol fraction of 35% was stacked to a thickness of 10 nm. At this time, Mg was doped using ethylcyclopentadienyl magnesium ((EtCp)₂Mg) as the raw material. Furthermore, a p-clad layer 6 composed of Mg-doped AlGaN having an AlN mol fraction of 25% was stacked to a thickness of 0.5 μm and finally, a p-contact layer 7 composed of Mg-doped GaN was stacked to a thickness of 50 nm.

After the completion of film formation, the temperature in the furnace was lowered to room temperature, and the wafer was taken out through the load-lock chamber.

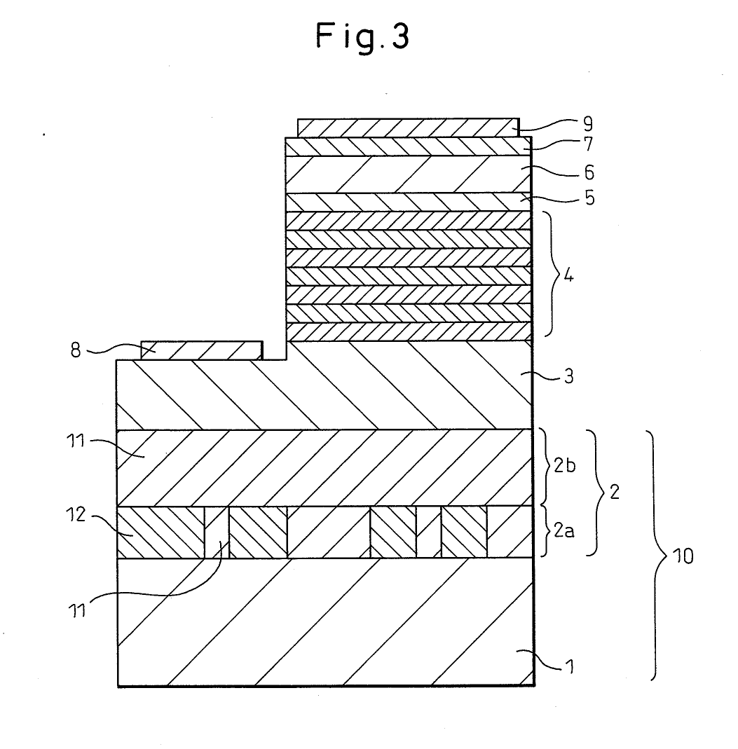

The wafer taken out was processed into a structure shown in FIG. 3, and Ti/Al/Ti/Au as an n-electrode 8 and Ni/Au as a p-electrode 9 were vapor-deposited and then each was alloyed to establish ohmic contact, thereby producing LED, as a result, the light emission wavelength was 335 nm and good current-voltage characteristics showing 5.8 V at a current of 100 mA were obtained. Also, the output was 1 mW. While the numerals in FIG. 3 are the same as in FIG. 2, 8 denotes an n-electrode and 9 denotes a p-electrode.

### Comparative Example 1

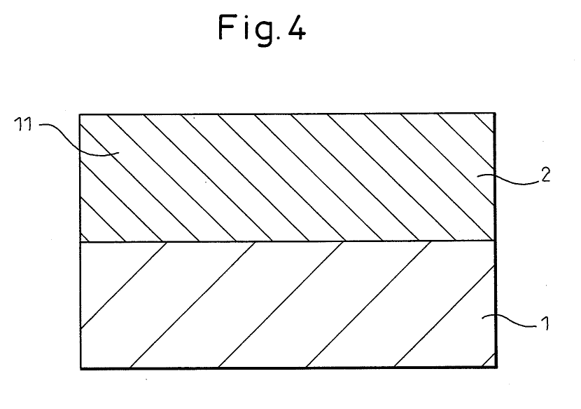

An AlN epitaxial substrate was produced under thoroughly the same conditions as in Example 1 except that in the AlN epitaxial substrate produced in Example 1, the conditions at the AlN growth were changed. FIG. 4 schematically illustrates the cross-sectional structure of the AlN epitaxial substrate produced in this Comparative Example. In the Figure, 1 is a base, 2 is an AlₓGa₁₋ₓN (0≦x≦1) layer, and 11 is a +C polarity crystal.

As for the conditions at the AlN growth, NH₃ and TMA were adjusted upon initiation of the growth such that the V/III ratio becomes 100, and AlN was grown for about 50 minutes under monitoring by an in-situ monitor to give the same total thickness as in Example 1.

As a result, a crystal with good surface state was obtained and when polarity judgment by KOH etching was performed in the same manner as in Example 1, the difference in level was 10 nm on average, from which the etching rate was determined to be 0.06 μm/hr. Since the value is 0.1 μm/hr or less, this was judged as +C polarity, and it was confirmed that the uppermost part of the epitaxial layer entirely has +C polarity. The full width at half maximum by X-ray diffraction of (0002) plane was 100 seconds and almost the same as that in Example 1, but the value of (10-10) plane was 1,500 seconds and by far worse than that in Example 1, and it was understood that the dislocation density is significantly large compared with Example 1.

Incidentally, in order to evaluate an AlN film grown by supplying an ammonia (NH₃) gas for 10 minutes into the vapor phase growth reaction furnace to give a V/III ratio of 100 in the early stage of growth, an epitaxial film formed by not performing but stopping the subsequent growth was judged for polarity in the same manner. The film thickness was 0.5 μm. A clearly etched portion in the portion not protected by a mask and a mask-protected and scarcely etched portion were uniformly flat on the entire surface, respectively. The etching rate was determined from the difference in level and found to be 0.06 μm/hr, and it was confirmed that the entire surface was a +C polarity plane.

### Comparative Example 2

LED was fabricated thoroughly in the same manner as in Example 2 by using the AlN epitaxial substrate produced in Comparative Example 1, as a result, the light emission wavelength was 335 nm and the same as that in Example 1, but the current-voltage characteristics showed a high voltage of 8 V at a current of 100 mA, and the output was 0.3 mW. It was understood that quality deterioration of the underlying crystal affects the electrical characteristics.

### INDUSTRIAL APPLICABILITY

The Group III nitride semiconductor epitaxial substrate of the present invention is assured of suppressed generation of cracking or dislocation and enhanced crystal quality and in turn, the Group III nitride semiconductor stacked thereon is also reduced in the generation of cracking or dislocation and enjoys enhanced crystal quality. Accordingly, the present invention has a very high utility value as a substrate of a Group III nitride semiconductor device such as a light-emitting device.

1. A Group III nitride semiconductor epitaxial substrate comprising a base and an AlₓGa₁₋ₓN (0≦x≦1) layer stacked on the base, wherein a layer allowing a crystal having −C polarity and a crystal having +C polarity to coexist is present on the base side of the AlₓGa₁₋ₓN (0≦x≦1) layer.

2. The Group III nitride semiconductor epitaxial substrate according to claim 1, wherein the surface layer opposite the base side of the AlₓGa₁₋ₓN (0<x≦1) layer is composed of only a crystal having +C polarity.

3. The Group III nitride semiconductor epitaxial substrate according to claim 1, wherein the range of x in the AlₓGa₁₋ₓN (0≦x≦1) layer is (0<x≦1).

4. The Group III nitride semiconductor epitaxial substrate according to claim 1, wherein in the layer allowing a crystal having −C polarity and a crystal having +C polarity to coexist, both the −C polarity crystal and the +C polarity crystal have a grain diameter of 10 to 5,000 nm.

5. The Group III nitride semiconductor epitaxial substrate according to claim 1, wherein the X-ray full width at half maximum of the (10-10) asymmetric plane of the AlₓGa₁₋ₓN (0≦x≦1) layer is 400 seconds or less.

6. The Group III nitride semiconductor epitaxial substrate according to claim 1, wherein the AlₓGa₁₋ₓN (0≦x≦1) layer is deposited using an MOVPE method.

7. The Group III nitride semiconductor epitaxial substrate according to claim 6, wherein the layer allowing a crystal having −C polarity and a crystal having +C polarity to coexist is deposited in the range of a V/III ratio of 20 to 2,000.

8. The Group III nitride semiconductor epitaxial substrate according to claim 6, wherein the V/III ratio when depositing the layer composed of only a crystal having +C polarity is smaller than the V/III ratio when depositing the layer allowing a crystal having −C polarity and a layer having +C polarity to coexist.

9. The Group III nitride semiconductor epitaxial substrate according to claim 6, wherein the layer allowing a crystal having −C polarity and a crystal having +C polarity to coexist is deposited at a temperature of 1,250° C. or more.

10. The Group III nitride semiconductor epitaxial substrate according to claim 1, wherein at least one member selected from sapphire, SiC, Si, ZnO and Ga₂O₃ is used for the base.

11. A Group III nitride semiconductor device obtained using the Group III nitride semiconductor epitaxial substrate according to claim 1.

12. A Group III nitride semiconductor ultraviolet or deep ultraviolet light-emitting device obtained using the Group III nitride semiconductor epitaxial substrate according to claim 2.
